(19) United States
(12) Patent Application Publication
(10) Pub. No.: US 2012/0240981 A1
(43) Pub. Date: Sep. 27, 2012

(54) WEATHERABLE LAYER FOR PHOTOVOLTAIC MODULE

(75) Inventors: Stephen Yau Sang Cheng, Hong Kong (HK); Ka-Lok Leung, Hong Kong (HK)

(73) Assignee: DU PONT APOLLO LTD., New Territories (HK)

(21) Appl. No.: 13/070,935

(22) Filed: Mar. 24, 2011

(51) Int. Cl. H01L 31/048; B32B 25/00

(52) U.S. Cl. 136/251; 428/492

(57) ABSTRACT

The invention relates to a photovoltaic (PV) module including a weatherable layer, wherein the weatherable layer comprises thermoplastic vulcanizate (TPV). The weatherable layer endows the PV module with excellent temperature resistance, weatherability, and chemical resistance.

### FIELD OF THE INVENTION

The present invention relates to the field of photovoltaic (PV) modules. Particularly, the present invention discloses a weatherable layer for PV modules.

### BACKGROUND OF THE INVENTION

Generally, a photovoltaic (PV) module is a semiconductor device capable of converting light energy, particularly solar energy, into electric energy using a photoelectric effect. A conventional PV module mainly comprises a substrate, photovoltaic cell(s), an encapsulant, such as ethylene vinyl acetate (EVA) or polyvinyl butyral (PVB), and a back protection layer (backsheet) including a weatherable layer.

In most applications, PV modules are mounted in an outside location such as on a rooftop, solar farm or supporting structure designed to support one or more PV modules. Thus, the sealed PV modules must have weatherablility and can resist moisture penetration when exposed to normal outdoor conditions (e.g., humid air, rain, snow, ice). Since PV modules are expected to perform over an extended time period, such as 20 to 25 years, the ability to resist the effects of the sun, rain or wind or such moisture penetration should last for such extended time period. If moisture penetrates into the modules and to the PV cells therein, the moisture will not only have an adverse affect on the appearance of the module but, more importantly, will ultimately result in the decreased performance or, possibly, total failure of the module. Therefore, it is important for the back protection layer to form a good seal to the PV module and be made of a material that resists moisture penetration and has good weatherability.

Recently, fluorinated polymeric materials have commonly been used as the back protection layer. For exemple, Tedlar®, a polyvinyl fluoride (PVF) material, or other fluorinated materials are used to protect PV modules requiring service in the field exposed to weathering conditions. To reduce cost, polyethylene terephthalate (PET) is also used in combination with the fluorinated polymeric materials. For example, the PVF/PET/PVF structure, a multi-layered laminated film, is commonly used as the back protection layer (backsheet) in the PV cell industry.

However, the above-mentioned fluorinated polymeric materials have a high cost, as well as limited supply. Therefore, there is a need for other polymer alternatives which can be used in outdoor environments for prolonged periods of time.

### SUMMARY OF THE INVENTION

In view of the problems described above, the present invention provides a photovoltaic (PV) module comprising a weatherable layer, wherein the weatherable layer comprises thermoplastic vulcanizate (TPV).

### BRIEF DESCRIPTION OF THE DRAWING

FIG. 1 shows an example of a backsheet with aluminum layer for a thin-film PV module.

FIG. 2 shows an example that the weatherable layer of the present invention is applied to a backsheet of a thin-film PV module.

FIG. 3 shows an example of a backsheet without aluminum layer for a crystalline silicon PV module.

FIG. 4 shows an example that the weatherable layer of the present invention is applied to a backsheet of a crystalline silicon PV module.

### DETAILED DESCRIPTION OF THE INVENTION

Features from different embodiments described below are examples of the elements recited in the claims and can be combined together into one embodiment without departing from the scope of the claims.

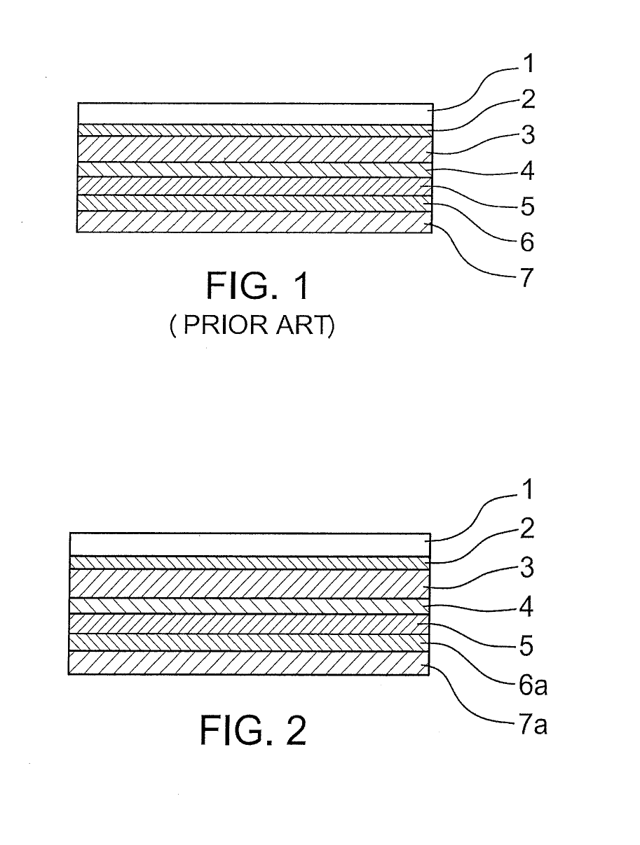

FIG. 1 shows the existing backsheet structure suitable for moisture sensitive thin-film PV modules, such as those of amorphous silicon, while FIG. 2 shows an equivalent backsheet incorporating the current invention.

As shown in FIG. 1, a conventional backsheet for a thin-film PV module mainly comprises a tie layer 1, an adhesive layer 2, a dielectric layer 3 (usually made from PET), an adhesive layer 4, a barrier layer 5 (e.g. an aluminum layer), an adhesive layer 6 and a weatherable layer 7 (Tedlar® or other fluorinated polymers).

As shown in FIG. 2, the present invention provides a backsheet of a thin-film PV module with a weatherable layer 7a made from thermoplastic vulcanizate (TPV). In addition, the materials of the adhesive layer 6a between the barrier layer 5 and the weatherable layer 7a may differ from those of the conventional one. For example, cyanoacrylate, acrylic or adhesives based on other materials are commercially available from major adhesive manufactures, which can be used to bond TPV to metals. Optionally, the weatherable layer 7a can bond directly to the barrier layer 5. Incorporation of the additive (such as an enthylene copolymer) which has specific adhesion to the barrier layer 5 (for example, an aluminum layer) enables the TPV compound to bond to the barrier layer 5 directly. Because the additive is a small portion of the blend, it does not materially change the nature of the original TPV. Basically, the UV resistance and weathering resistance properties still come from the nature of the TPV itself.

The barrier layer 5 can be metallic, polymeric, inorganic or the combination thereof. Preferably, an aluminum barrier layer is preferred. The barrier layer 5 preferably has a thickness of at least 1 micron, more preferably at least 10 microns, and most preferably at least 25 microns. The adhesive layer 4 between the dielectric layer 3 and barrier layer 5 can be any type or form of adhesive which enables the bonding of the two layers. For example, two-part polyurethane adhesives are used for bonding the aluminum barrier layer to the PET dielectric layer.

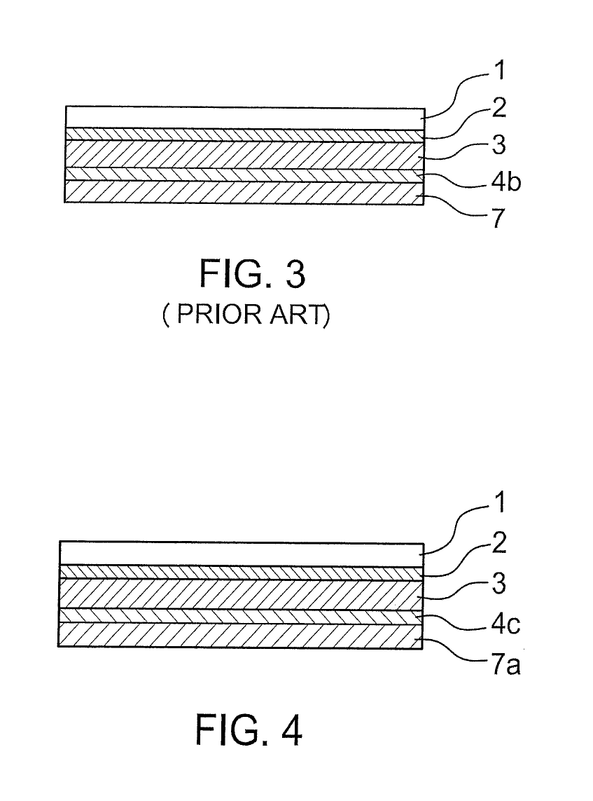

FIG. 3 shows the existing backsheet structure suitable for less moisture sensitive PV modules, such as those made from crystalline silicon, while FIG. 4 shows an equivalent backsheet incorporating the current invention.

As shown in FIG. 3, a conventional backsheet for a crystalline silicon PV module mainly comprises a tie layer 1, an adhesive layer 2, a dielectric layer 3 (usually made from PET), an adhesive layer 4b and a weatherable layer 7 (Tedlar® or other fluorinated polymers).

As shown in FIG. 4, the present invention provides a backsheet of a crystalline silicon PV module with a weatherable layer 7a made from TPV. In addition, the materials of the adhesive layer 4c between the dielectric layer 3 and the weatherable layer 7a may differ from those of the adhesive layer 4b. For example, two-part polyurethane adhesives from major adhesive manufactures can be used to bond TPV to PET.

The purpose of the tie layer 1 is to enable the adhesion of the dielectric layer to the encapsulant of the PV module (usually EVA, not shown). The Tie Layer 1 is usually composed of a polymer of EVA of vinylacetate comonomer content of around 4-8%, which has compatibility with the EVA polymer in the encapsulation film to effect bonding. It is also known that some manufacturers use linear low-density polyethylene (LLDPE) as the tie layer material. The dielectric layer 3 can be made from any suitable electrically insulating materials, such as but not limited to PET, and preferably has a thickness of at least 0.05 mm, more preferably at least 0.1 mm, and most preferably at least 0.2 mm.

Thermoplastic vulcanizates (TPVs) include blends of dynamically cured rubber and thermoplastic resin. The rubber may be dispersed within the thermoplastic resin phase as finely-divided rubber particles. These compositions have advantageously demonstrated many of the properties of thermoset elastomers, yet they are processable as thermoplastics.

TPVs are created under a dynamic vulcanization process. For example, one of the earlier TPVs is based on EPDM-PP systems. TPVs based on EPDM (ethylene propylene diene monomer (M-class) rubber) and polypropylene (PP) involve the vulcanization of EPDM while undergoing phase inversion to result in finely dispersed crosslinked EPDM phase in a PP matrix. The resulting material generally exhibits excellent weather resistant properties imparted by the crosslinked EPDM, while possessing thermoplastic processing attributes due to the thermoplastic matrix. For instance, according to the product information of Santoprene® Thermoplastic Vulcanizates (manufactured by ExxonMobil Chemical; Technical Literature TL01007), the UV resistance of TPV shows that the materials can withstand 5000 hours of UV exposure while retaining 80% of original properties under test conditions which are equivalent of a total UV energy exposure of more than 672 MJ/m² (or 186.7 kWh/m²) of wavelength up to 380 nm. However, IEC 61646 test standard for UV resistance of thin-film PV modules utilizes a total UV energy exposure of only 15 kWh/m² of wavelength up to 385 nm, which is less than 10 times the severity of the performance of TPV. Minor differences in test conditions aside, the order of magnitude weatherability of TPVs indicates that they can be used to provide weathering resistance for a PV module.

The weatherable layer of the present invention comprises thermoplastic vulcanizate (TPV) consisting essentially of a crosslinkable rubber dispersed in a thermoplastic resin. The crosslinkable rubber is selected from the group consisting of EPDM, polyolefin elastomers, silicone and the combination thereof. Preferably, the crosslinkable rubber is EPDM. The thermoplastic resin is selected from the group consisting of polypropylene, polyamide and the combination thereof. Preferably, the thermoplastic resin is polypropylene. TPV is made by dynamic vulcanization, in which the crosslinkable rubber phase undergoes phase inversion. Because the rubber in practice is the dominant material, it becomes the domain phase in the process. Thus, the crosslinkable rubber practically is more than 50% weight in the TPV, while the thermoplastic resin is less than 50% weight in the TPV. The crosslinkable rubber is preferably more than 60% weight, more preferably more than 70% weight in the TPV.

The weatherable layer of the present invention preferably comprises more than 60% weight TPV, more preferably comprises more than 70% weight TPV.

The weatherable layer of the present invention is easily processed in the manufacture of PV modules. The weatherable layer can be in any form to be applied to protect the PV module, exemplified but not limited to the following forms: film, sheet, dispersion, solvent solution and melt. The weatherable layer may be produced as a sheet or film by known processes, such as extrusion, cell cast, injection molding, compression molding, calendaring, blow molding, and continuous cast. The weatherable layer of the present invention has a thickness of at least 1 micron, more preferably at least 10 microns, and most preferably at least 25 microns.

According to one aspect of the present invention, the weatherable layer may contain one or more additives in an effective amount, including but not limited to impact UV stabilizers - which may be organic stabilizers (for example, UV absorbers and UV stabilizers) or inorganic particles (for example, titanium dioxide or carbon black) for permanent UV protection; plasticizers (such as paraffinic oil); fillers (such as calcium carbonate or talc); coloring agents or pigments; antioxidants (such as phenolic antioxidants); antistatic agents; surfactants; toners; lubricants; processing aids and dispersing aids.

By applying the present invention, the PV module will be excellent in weatherability, outdoor temperature resistance, and chemical resistance. Therefore, the PV module can maintain high performance for a long term.

### EXAMPLE

An example of the present invention will be described. The example illustrates a preferable embodiment of the present invention, and the present invention is not limited to the example.

### Example 1

The backsheet of a PV module which can be illustrated by FIG. 2, comprises EVA as a tie layer 1, PU as an adhesive layer 2, PET as a dielectric layer 3, PU as an adhesive layer 4, an aluminum layer as a barrier layer 5, an adhesive layer 6a and a weatherable layer 7a.

The weatherable layer can be a compounded TPV provided by specialty compounders or comprises such a TPV further compounded with additional materials. In one embodiment, two grades (N40 and N70) of Elastoplas® TPV KP-500N series were obtained from Kuo Ching Chemical Company. These two TPV materials were further compounded with PP (Total Petrochemical Polypropylene PPC 2660 resin), calcium carbonate and carbon black 50% black content in PE carrier masterbatch (Grade name of GP 1010A) sourced locally in Taiwan. The preparation of the compounds was carried out by Plastics Industry Development Center (PIDC), a research institute in Taiwan. Compound #1 consists of N40/PP/CaCO₃/masterbatch at a 85/12/13/5 weight ratio, while Compound #2 consists of N70/CaCO₃/masterbatch at a 97/13/5 ratio. Compound #1 had initial mechanical properties of 52.9 kg/cm2 and 130% for tensile strength at break and elongation at break, respectively. After UV-A exposure for 500 hours, Compound #1 had mechanical properties of 51.3 kg/cm2 and 130% for tensile strength at break and elongation at break, respectively. For Compound #2, the results were 70.3 kg/cm2 and 180% before aging versus 74.9 kg/cm2 and 180% after UV-A exposure. Clearly, Compounds #1 and 2 shows that the TPV materials did not undergo significant degradation in mechanical properties after UV-A exposure and can be a weatherable layer of a photovoltaic module.

### Example 2

In another embodiment, Compounds #1 and #2 were further compounded with adhesion promoting co-polymers, such as Lotader AX-8840 manufactured by Arkema Inc. The co-polymer was added to Compounds #1 and #2, resulting in Compound #1a with a composition of #1/Lotader=90/10 by weight and Compound #2a with a composition of #2/Lotader=90/10 by weight. The preparation of the compositions was carried out by PIDC. Compounds #1a and #2a were put on top of aluminum foil, and melted and pressed at 220 deg C. The incorporation of Lotader AX-8840 enabled the adhesion directly onto aluminum foil. The TPV surfaces were cut with a blade, and the cut locations were bent backwards to expose the TPV/Aluminum interface. Attempts were tried to peel off the TPV layers at the interface. Delamination can be initiated for Compound #1a. If de-lamination is forced to initiate, some part of aluminum foil become destroyed in the process. For Compound #2a, de-lamination cannot be initiated at the cut interface. Clearly, it shows that both Compounds #la and #2a can be a weatherable layer of a photovoltaic module. Example 2 also shows that either an adhesive layer 6a can be used or the weatherable layer 7a can bond directly to an aluminum layer in the PV module of the present invention.

What is claimed is:

1. A photovoltaic (PV) module comprising a weatherable layer, wherein the weatherable layer comprises thermoplastic vulcanizate (TPV) consisting essentially of a crosslinkable rubber dispersed in a thermoplastic resin.

2. The PV module of claim 1, wherein the crosslinkable rubber is selected from the group consisting of ethylene propylene diene monomer (M-class) rubber (EPDM), polyolefin elastomers, silicone and the combination thereof.

3. The PV module of claim 2, wherein the crosslinkable rubber is EPDM.

4. The PV module of claim 1, wherein the thermoplastic resin is selected from the group consisting of polypropylene, polyamide and the combination thereof.

5. The PV module of claim 4, wherein the thermoplastic resin is polypropylene.

6. The PV module of claim 1, wherein the weatherable layer is at least 1 micron, preferably at least 10 microns.

7. A backsheet for a PV module comprising:
a dielectric layer;
a barrier layer;
an adhesive layer between the barrier layer and the dielectric layer;
a weatherable layer comprises thermoplastic vulcanizate (TPV); and
optionally an adhesive layer between the barrier layer and the weatherable layer.

8. A backsheet for a PV module comprising:
a dielectric layer;
a weatherable layer comprises thermoplastic vulcanizate (TPV); and
an adhesive layer between the dielectric layer and the weatherable layer.
